(19) United States
(12) Patent Application Publication
(10) Pub. No.: US 2024/0113690 A1
(43) Pub. Date: Apr. 4, 2024

(54) METHOD FOR MANUFACTURING VIBRATOR

(71) Applicant: SEIKO EPSON CORPORATION, Tokyo (JP)

(72) Inventors: Tsukasa Watanabe, Minamiminowa-mura (JP); Keiichi Yamaguchi, Ina-shi (JP); Shigeru Shiraishi, Ina-shi (JP); Ryuta Nishizawa, Nagano-shi (JP)

(21) Appl. No.: 18/475,673

(22) Filed: Sep. 27, 2023

(30) Foreign Application Priority Data
Sep. 29, 2022 (JP) 2022-155985

(51) Int. Cl. H03H 9/215; H03H 3/02

(52) U.S. Cl. CPC H03H 9/215; H03H 3/02; H03H 2003/026

(57) ABSTRACT

A method for manufacturing a vibrator includes a preparation step of preparing a quartz crystal substrate having a first surface and a second surface which are in a front and back relationship, a first film formation step of forming a first stacked body by sequentially stacking a first underlying film, a second underlying film, and a first protective film at the first surface, a first patterning step of patterning the first stacked body in a manner in which the first underlying film, the second underlying film, and the first protective film remain in a region of an element formation region other than a first groove formation region and a second groove formation region, the first underlying film and the second underlying film remain in the first groove formation region, and the first underlying film remains in the second groove formation region, and a first dry etching step of dry etching the quartz crystal substrate from the first surface through the first stacked body.

The present application is based on, and claims priority from JP Application Serial Number 2022-155985, filed Sep. 29, 2022, the disclosure of which is hereby incorporated by reference herein in its entirety.

### BACKGROUND

### 1. Technical Field

The present disclosure relates to a method for manufacturing a vibrator.

### 2. Related Art

JP-A-2007-013382 discloses a method for manufacturing a quartz crystal vibrator element including a pair of vibration arms each having a groove on a front surface and a lower surface, in which an outer shape of the quartz crystal vibrator element and the groove of each of the vibration arms are collectively formed by using a micro loading effect of dry etching. The “micro loading effect” refers to an effect in which, at a dense portion having a small processing width and a sparse portion having a large processing width, a processing depth is larger, that is, an etching rate is larger, in the sparse portion than in the dense portion even when dry etching is performed under the same condition.

However, in JP-A-2007-013382, since the outer shape and the grooves are collectively formed by using the micro loading effect, the outer shape such as a width of the vibration arms and a separation distance between the vibration arms, and a groove shape such as widths and depths of the grooves are restricted. Therefore, the degree of freedom in design is low, and for example, there is a problem that grooves having the same width and different depths cannot be formed in a plurality of vibration arms.

### SUMMARY

A method for manufacturing a vibrator according to the present disclosure is a method for manufacturing a vibrator including a first vibration arm that has a first surface and a second surface which are in a front and back relationship and that has a bottomed first groove opened in the first surface, and a second vibration arm that has a bottomed second groove opened in the first surface. The method includes: a preparation step of preparing a quartz crystal substrate having the first surface and the second surface; a first film formation step of forming a first stacked body by sequentially stacking a first underlying film, a second underlying film, and a first protective film at the first surface; a first patterning step of patterning the first stacked body in a manner in which the first underlying film, the second underlying film, and the first protective film remain in a region of an element formation region other than a first groove formation region and a second groove formation region, the first underlying film and the second underlying film remain in the first groove formation region, and the first underlying film remains in the second groove formation region, when a region of the quartz crystal substrate where the vibrator is formed is referred to as the element formation region, a region where the first groove is formed is referred to as the first groove formation region, and a region where the second groove is formed is referred to as the second groove formation region; and a first dry etching step of dry etching the quartz crystal substrate from the first surface through the first stacked body.

### BRIEF DESCRIPTION OF THE DRAWINGS

FIG. 1 is a plan view showing a vibrator according to a first embodiment.

FIG. 2 is a cross-sectional view taken along a line A-A in FIG. 1.

FIG. 3 is a cross-sectional view taken along a line B-B in FIG. 1.

FIG. 4 is a schematic diagram showing a drive state of the vibrator.

FIG. 5 is a schematic diagram showing a drive state of the vibrator.

FIG. 6 is a graph showing a relationship between d1, d2 and sensitivity when d1=d2.

FIG. 7 is a graph showing a relationship between d2/d1 and sensitivity.

FIG. 8 is a flowchart showing a method for manufacturing the vibrator.

FIG. 9 is a cross-sectional view showing the method for manufacturing the vibrator.

FIG. 10 is a cross-sectional view showing the method for manufacturing the vibrator.

FIG. 11 is a cross-sectional view showing the method for manufacturing the vibrator.

FIG. 12 is a cross-sectional view showing the method for manufacturing the vibrator.

FIG. 13 is a cross-sectional view showing the method for manufacturing the vibrator.

FIG. 14 is a cross-sectional view showing the method for manufacturing the vibrator.

FIG. 15 is a cross-sectional view showing the method for manufacturing the vibrator.

FIG. 16 is a cross-sectional view showing the method for manufacturing the vibrator.

FIG. 17 is a cross-sectional view showing the method for manufacturing the vibrator.

FIG. 18 is a cross-sectional view showing the method for manufacturing the vibrator.

FIG. 19 is a cross-sectional view showing the method for manufacturing the vibrator.

FIG. 20 is a cross-sectional view showing the method for manufacturing the vibrator.

FIG. 21 is a cross-sectional view showing the method for manufacturing the vibrator.

FIG. 22 is a cross-sectional view showing the method for manufacturing the vibrator.

FIG. 23 is a cross-sectional view showing the method for manufacturing the vibrator.

FIG. 24 is a cross-sectional view showing the method for manufacturing the vibrator.

FIG. 25 is a cross-sectional view showing the method for manufacturing the vibrator.

FIG. 26 is a cross-sectional view showing the method for manufacturing a vibrator.

FIG. 27 is a cross-sectional view showing the method for manufacturing the vibrator.

FIG. 28 is a cross-sectional view showing a method for manufacturing a vibrator according to a second embodiment.

FIG. 29 is a cross-sectional view showing the method for manufacturing the vibrator according to the second embodiment.

FIG. 30 is a cross-sectional view showing the method for manufacturing the vibrator according to the second embodiment.

FIG. 31 is a cross-sectional view showing the method for manufacturing the vibrator according to the second embodiment.

FIG. 32 is a cross-sectional view showing the method for manufacturing the vibrator according to the second embodiment.

FIG. 33 is a cross-sectional view showing the method for manufacturing the vibrator according to the second embodiment.

FIG. 34 is a plan view showing a vibrator according to a third embodiment.

FIG. 35 is a cross-sectional view showing a vibrator according to a modification.

FIG. 36 is a cross-sectional view showing a vibrator according to a modification.

FIG. 37 is a cross-sectional view showing a method for manufacturing a vibrator.

### DESCRIPTION OF EMBODIMENTS

Hereinafter, a method for manufacturing a vibrator according to the present disclosure will be described in detail based on embodiments illustrated with reference to the accompanying drawings.

### First Embodiment

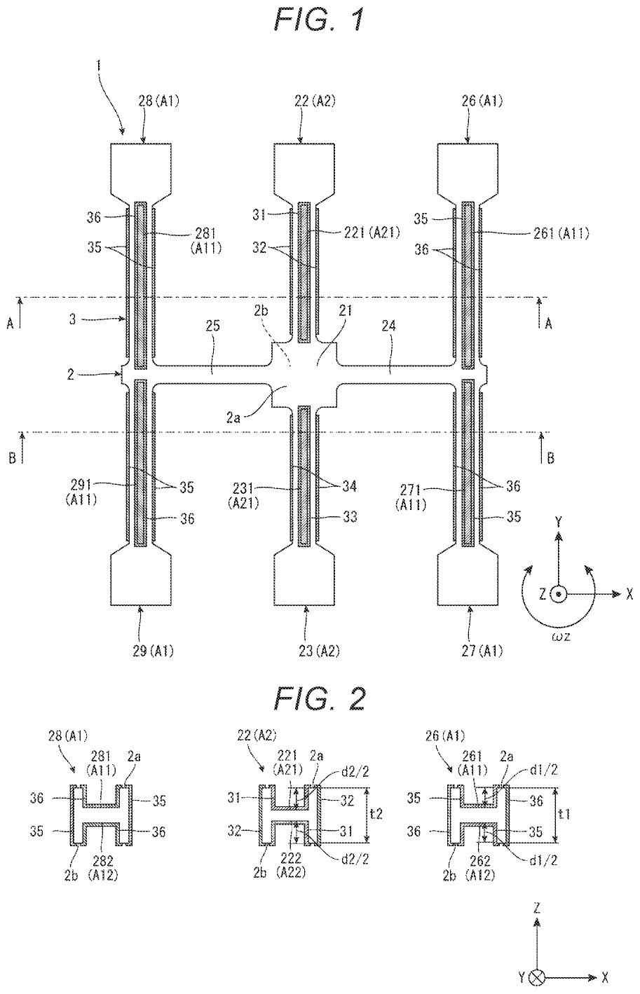

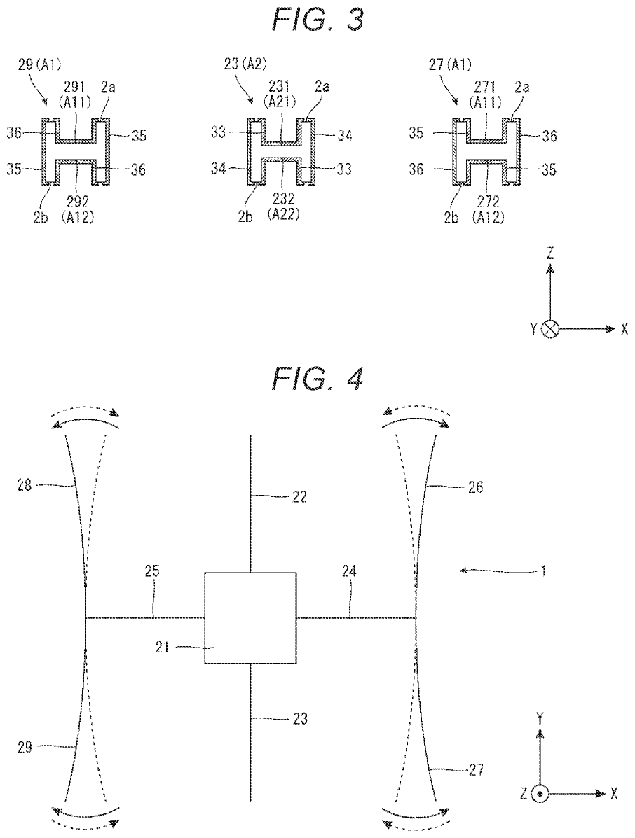

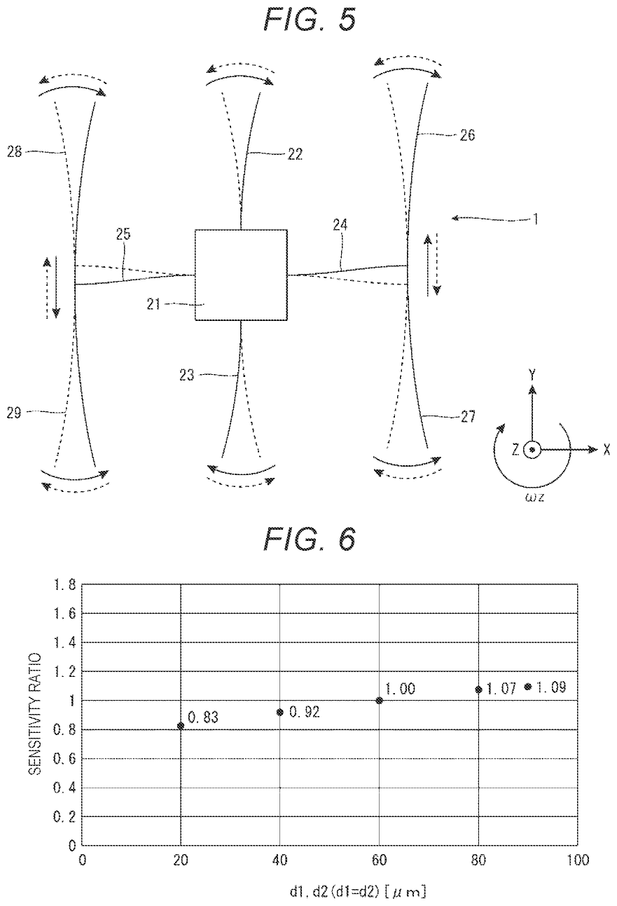

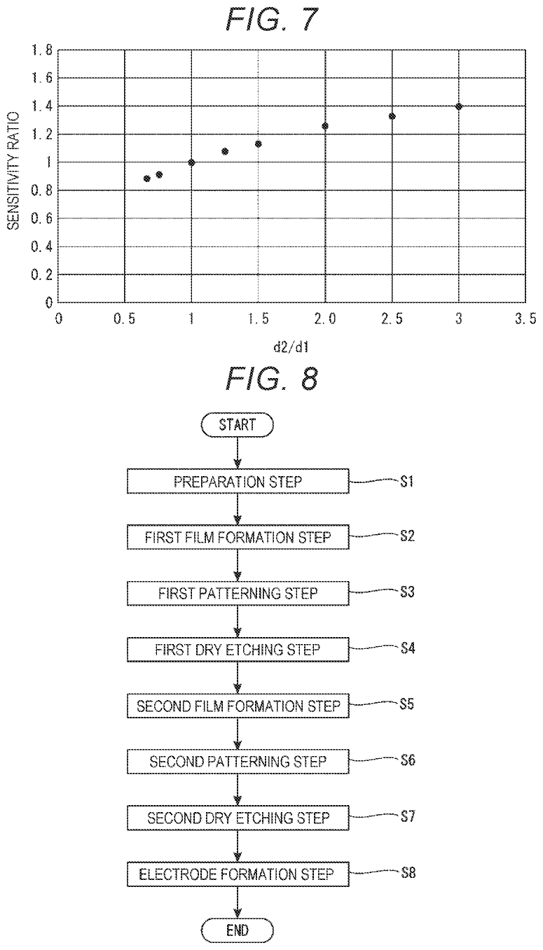

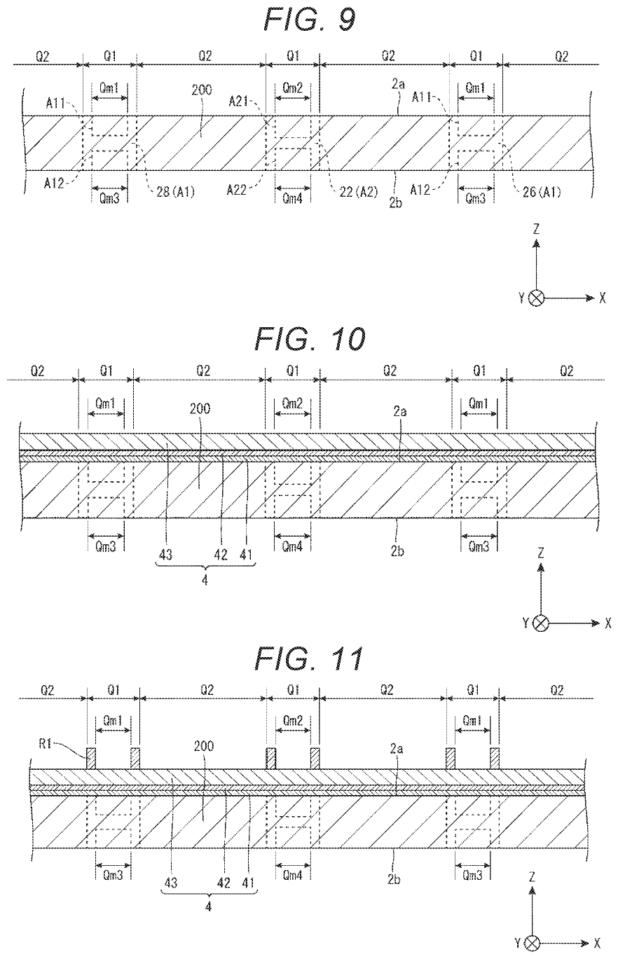

FIG. 1 is a plan view showing a vibrator according to a first embodiment. FIG. 2 is a cross-sectional view taken along a line A-A in FIG. 1. FIG. 3 is a cross-sectional view taken along a line B-B in FIG. 1. FIGS. 4 and 5 are schematic diagrams showing drive states of the vibrator. FIG. 6 is a graph showing a relationship between d1, d2 and sensitivity when d1=d2. FIG. 7 is a graph showing a relationship between d2/d1 and sensitivity. FIG. 8 is a flowchart showing a method for manufacturing the vibrator. FIGS. 9 to 27 are cross-sectional views showing the method for manufacturing the vibrator.

Hereinafter, an X-axis, a Y-axis, and a Z-axis which are three axes orthogonal to one another are shown for the convenience of description. A direction along the X-axis is also referred to as an X-axis direction, a direction along the Y-axis is also referred to as a Y-axis direction, and a direction along the Z-axis is also referred to as a Z-axis direction. An arrow side of each axis is also referred to a “positive side”, and an opposite side is also referred to a “negative side”. A positive side in the Z-axis direction is also referred to as “up”, and a negative side in the Z-axis direction is also referred to as “down”. A plan view from the Z-axis direction is also simply referred to as a “plan view”.

First, a vibrator 1 manufactured using a method for manufacturing a vibrator according to the embodiment will be described. The vibrator 1 is an angular velocity detection element capable of detecting an angular velocity ωz around the Z-axis. As shown in FIGS. 1 to 3, the vibrator 1 includes a vibration substrate 2 formed by patterning a Z-cut quartz crystal substrate, and an electrode 3 deposited on a surface of the vibration substrate 2.

The vibration substrate 2 has a thickness in the Z-axis direction, has a plate shape extending in an X-Y plane, and has an upper surface 2a serving as a first surface and a lower surface 2b serving as a second surface which are in a front and back relationship. The vibration substrate 2 includes a base portion 21 located in a center portion of the vibration substrate 2, a pair of detection vibration arms 22 and 23 serving as a second vibration arm A2 extending from the base portion 21 to both sides in the Y-axis direction, a pair of support arms 24 and 25 extending from the base portion 21 to both sides in the X-axis direction, a pair of drive vibration arms 26 and 27 serving as a first vibration arm A1 extending from a tip end portion of the support arm 24 to both sides in the Y-axis direction, and a pair of drive vibration arms 28 and 29 serving as the first vibration arm A1 extending from a tip end portion of the support arm 25 to both sides in the Y-axis direction. The base portion 21 is supported by a support member (not shown).

According to the vibrator 1 having such a shape, as will be described later, since the drive vibration arms 26, 27, 28, and 29 perform flexural vibrations in a balanced manner in a drive vibration mode, an unnecessary vibration is less likely to occur in the detection vibration arms 22 and 23, and the angular velocity ωz can be accurately detected.

The detection vibration arm 22 has a bottomed groove 221 serving as a second groove A21 formed in the upper surface 2a and a bottomed groove 222 serving as a fourth groove A22 formed in the lower surface 2b. The grooves 221 and 222 are formed along the detection vibration arm 22. The grooves 221 and 222 are formed symmetrically.

The detection vibration arm 23 has a bottomed groove 231 serving as the second groove A21 formed in the upper surface 2a and a bottomed groove 232 serving as the fourth groove A22 formed in the lower surface 2b. The grooves 231 and 232 are formed along the detection vibration arm 23. The grooves 231 and 232 are formed symmetrically.

The two detection vibration arms 22 and 23 are designed to have the same configuration (shape and dimension).

The drive vibration arm 26 has a bottomed groove 261 as a first groove A11 formed in the upper surface 2a and a bottomed groove 262 serving as a third groove A12 formed in the lower surface 2b. The grooves 261 and 262 are formed along the drive vibration arm 26. The grooves 261 and 262 are formed symmetrically.

The drive vibration arm 27 has a bottomed groove 271 serving as the first groove A11 formed in the upper surface 2a and a bottomed groove 272 serving as the third groove A12 formed in the lower surface 2b. The grooves 271 and 272 are formed along the drive vibration arm 27. The grooves 271 and 272 are formed symmetrically.

The drive vibration arm 28 has a bottomed groove 281 serving as the first groove A11 formed in the upper surface 2a and a bottomed groove 282 serving as the third groove A12 formed in the lower surface 2b. The grooves 281 and 282 are formed along the drive vibration arm 28. The grooves 281 and 282 are formed symmetrically.

The drive vibration arm 29 has a bottomed groove 291 serving as the first groove A11 formed in the upper surface 2a and a bottomed groove 292 serving as the third groove A12 formed in the lower surface 2b. The grooves 291 and 292 are formed along the drive vibration arm 29. The grooves 291 and 292 are formed symmetrically.

The four drive vibration arms 26, 27, 28, and 29 are designed to have the same configuration (shape and dimension).

The electrode 3 includes a first detection signal electrode 31, a first detection ground electrode 32, a second detection signal electrode 33, a second detection ground electrode 34, a drive signal electrode 35, and a drive ground electrode 36. The first detection signal electrode 31 is disposed on the upper surface 2a and the lower surface 2b of the detection vibration arm 22, and the first detection ground electrode 32 is disposed on both side surfaces of the detection vibration arm 22. The second detection signal electrode 33 is disposed on the upper surface 2a and the lower surface 2b of the detection vibration arm 23, and the second detection ground electrode 34 is disposed on both side surfaces of the detection vibration arm 23. The drive signal electrode 35 is disposed on the upper surfaces 2a and the lower surfaces 2b of each of the drive vibration arms 26 and 27 and on both side surfaces of each of the drive vibration arms 28 and 29. The drive ground electrode 36 is disposed on both side surfaces of each of the drive vibration arms 26 and 27 and on the upper surface 2a and the lower surface 2b of each of the drive vibration arms 28 and 29.

The configuration of the vibrator 1 is briefly described above. The vibrator 1 having such a configuration detects the angular velocity ωz around the Z-axis as follows.

When a drive signal is applied between the drive signal electrode 35 and the drive ground electrode 36, as shown in FIG. 4, the drive vibration arms 26 and 27 and the drive vibration arms 28 and 29 perform flexural vibrations in opposite phases in the X-axis direction (hereinafter, this state is also referred to as a “drive vibration mode”). In this state, vibrations of the drive vibration arms 26, 27, 28, and 29 are in balance, and the detection vibration arms 22 and 23 do not vibrate. When an angular velocity ωz is applied to the vibrator 1 in a state where the vibrator 1 is driven in the drive vibration mode, as shown in FIG. 5, a Coriolis force acts on the drive vibration arms 26, 27, 28, and 29 to excite a flexural vibration in the Y-axis direction, and the detection vibration arms 22 and 23 perform a flexural vibration in the X-axis direction in response to the excited flexural vibration (hereinafter, this state is also referred to as a “detection vibration mode”).

Electric charges generated in the detection vibration arm 22 due to such a flexural vibration are read out as a first detection signal from the first detection signal electrode 31, electric charges generated in the detection vibration arms 23 are read out as a second detection signal from the second detection signal electrode 33, and the angular velocity ωz is calculated based on the first and second detection signals. Since the first and second detection signals have opposite phases, the angular velocity ωz can be detected more accurately by using a differential detection method.

Next, a relationship between the grooves formed in the detection vibration arms 22 and 23 and the grooves formed in the drive vibration arms 26, 27, 28, and 29 will be described. As described above, the detection vibration arms 22 and 23 have the same configuration, and the drive vibration arms 26, 27, 28, and 29 have the same configuration. Hereinafter, for the convenience of description, the detection vibration arms 22 and 23 are collectively referred to as the second vibration arm A2, and the drive vibration arms 26, 27, 28, and 29 are collectively referred to as the first vibration arm A1.

As described above, the first vibration arm A1 has the first groove A11 formed in the upper surface 2a and the third groove A12 formed in the lower surface 2b. The second vibration arm A2 has the second groove A21 formed in the upper surface 2a and the fourth groove A22 formed in the lower surface 2b. Therefore, a cross-sectional shape of each of the first vibration arm A1 and the second vibration arm A2 is an H shape. According to such a configuration, it is possible to increase a length of a heat transfer path during a flexural vibration of the first and second vibration arms A1 and A2, a thermoelastic loss is reduced, and a Q value is increased. Further, the first and second vibration arms A1 and A2 are soft, and are easily flexed and deformed in the X-axis direction. Therefore, an amplitude of the first vibration arm A1 in the drive vibration mode can be increased. As the amplitude of the first vibration arm A1 increases, the Coriolis force increases, and an amplitude of the second vibration arm A2 in the detection vibration mode increases. Therefore, a large detection signal is obtained, and detection sensitivity of the angular velocity ωz is increased.

Hereinafter, as shown in FIG. 2, a relationship between d2/t2 and d1/t1 will be described in detail, in which t1 is a thickness of the first vibration arm A1, d1 is a depth of the first and third grooves A11 and A12 of the first vibration arm A1, t2 is a thickness of the second vibration arm A2, and d2 is a depth of the second and fourth grooves A21 and A22. d1 is a total depth of the first and third grooves A11 and A12. In the embodiment, since the first and third grooves A11 and A12 are formed symmetrically, a depth of each of the first and third grooves A11 and A12 is d1/2. Similarly, d2 is a total depth of the second and fourth grooves A21 and A22. In the embodiment, since the second and fourth grooves A21 and A22 are formed symmetrically, a depth of each of the second and fourth grooves A21 and A22 is d2/2.

FIG. 6 shows a relationship between d1, d2 (d1=d2) and detection sensitivity (sensitivity) of the angular velocity ωz. A plate thickness of the vibration substrate 2, that is, t1 and t2, is 100 μm. The detection sensitivity is represented by a ratio by setting the detection sensitivity when d1 and d2 are 60 μm to 1. As can be seen from the figure, the detection sensitivity increases as d1 and d2 become larger. When d1 and d2 are 90 μm (90% of the plate thickness), the detection sensitivity is only 1.09 times higher than the detection sensitivity when d1 and d2 are 60 μm (60% of the plate thickness). Therefore, it can be seen that when d1=d2, it is difficult to increase the detection sensitivity even when d1 and d2 are increased.

FIG. 7 shows a relationship between d2/d1 and the detection sensitivity. A plate thickness of the vibration substrate 2, that is, t1 and t2, is 100 μm. The detection sensitivity is represented by a ratio by setting the detection sensitivity when d2/d1=1 in a configuration in the related art to 1. As can be seen from the figure, the detection sensitivity increases as d2/d1 increases. That is, the deeper the second and fourth grooves A21 and A22 of the second vibration arm A2 relative to the first and third grooves A11 and A12 of the first vibration arm A1, the higher the detection sensitivity. It can be seen that the detection sensitivity can be increased as compared with a configuration in the related art in a region of d2/d1>1.

Accordingly, in the vibrator 1, d2/d1>1, that is, d2/t2>d1/t1. That is, the first and third grooves A11 and A12 are shallower than the second and fourth grooves A21 and A22. Accordingly, the detection sensitivity can be increased as compared with the configuration in the related art, and the detection sensitivity that cannot be achieved by the configuration in the related art can be obtained.

The overall configuration of the vibrator 1 is described above. Next, a method for manufacturing the vibrator 1 will be described. Here, the drive vibration arms 26, 27, 28, and 29 are also collectively referred to as the first vibration arm A1, and the detection vibration arms 22 and 23 are also collectively referred to as the second vibration arm A2. As shown in FIG. 8, the method for manufacturing the vibrator 1 includes a preparation step S1, a first film formation step S2, a first patterning step S3, a first dry etching step S4, a second film formation step S5, a second patterning step S6, a second dry etching step S7, and an electrode formation step S8. Hereinafter, the steps S1 to S8 will be described in order using a cross-sectional view corresponding to the view shown in FIG. 2.

### Preparation Step S1

First, as shown in FIG. 9, a Z-cut quartz crystal substrate 200 which is a base material of the vibration substrate 2 is prepared. The quartz crystal substrate 200 has the upper surface 2a serving as a first surface and the lower surface 2b serving as a second surface which are in a front and back relationship. The quartz crystal substrate 200 is larger than the vibration substrate 2, and a plurality of vibration substrates 2 can be formed from the quartz crystal substrate 200. A quartz crystal wafer obtained by Z-cutting a lumbered synthetic quartz crystal can be used as the quartz crystal substrate 200.

Hereinafter, a region where the vibration substrate 2 is formed is referred to as an element formation region Q1, a region other than the element formation region Q1 is referred to as a removal region Q2, a region where the first groove A11 is formed is referred to as a first groove formation region Qm1, a region where the second groove A21 is formed is referred to as a second groove formation region Qm2, a region where the third groove A12 is formed is referred to as a third groove formation region Qm3, and a region where the fourth groove A22 is formed is referred to as a fourth groove formation region Qm4.

Next, if necessary, both surfaces of the quartz crystal substrate 200 are polished for thickness adjustment and planarization. Such polishing is also referred to as lapping. For example, a wafer polishing device including a pair of upper and lower surface plates is used, the quartz crystal substrate 200 is interposed between the surface plates that rotate in opposite directions, and both surfaces of the quartz crystal substrate 200 are polished while the quartz crystal substrate 200 is rotated and a polishing liquid is supplied. In the polishing, mirror polishing may be performed on both surfaces of the quartz crystal substrate 200 as necessary following the lapping described above. Such polishing is also referred to polishing processing. Accordingly, both surfaces of the quartz crystal substrate 200 can be mirror-finished.

### First Film Formation Step S2

Next, as shown in FIG. 10, a first underlying film 41, a second underlying film 42, and a first protective film 43 are formed in this order on the upper surface 2a of the quartz crystal substrate 200 to form a first stacked body 4. A film formation method is not particularly limited, and sputtering, vapor deposition, or the like can be used.

Among the films included in the first stacked body 4, at least the first underlying film 41 and the second underlying film 42 are formed of a material that is etched at a predetermined etching rate in a first dry etching step S4 to be described later.

In the embodiment, the first underlying film 41, the second underlying film 42, and the first protective film 43 are metal films made of metal materials. Accordingly, excellent etching resistance (high etching rate ratio) can be exhibited, and the films 41, 42, and 43 can be thinned. Therefore, time required for forming the first stacked body 4 can be shortened, and a manufacturing time of the vibrator 1 can be shortened. Since a film thickness can be reduced, patterning accuracy of the films 41, 42, and 43 is improved.

In particular, in the embodiment, the first underlying film 41 is made of chromium (Cr), the second underlying film 42 is made of copper (Cu), and the first protective film 43 is made of nickel (Ni). Since the first underlying film 41 is made of chromium (Cr), the first stacked body 4 having excellent adhesion to the quartz crystal substrate 200 is obtained. Therefore, the first dry etching step S4 can be performed with high accuracy.

Component materials of the first underlying film 41, the second underlying film 42, and the first protective film 43 are not limited to metal materials, and for example, at least one of the films is a resist material.

### First Patterning Step S3

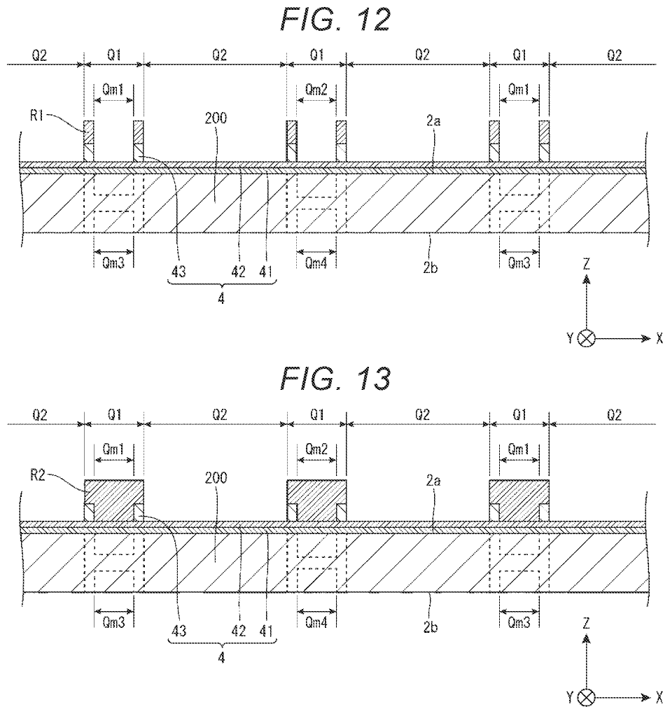

Next, as shown in FIG. 11, a first resist film R1 is formed on the first stacked body 4 and is patterned using a photolithography technique. The first resist film R1 overlaps a region of the element formation region Q1 other than the first groove formation region Qm1 and the second groove formation region Qm2. Next, as shown in FIG. 12, the first protective film 43 is etched from the upper surface 2a through the first resist film R1, and a portion not overlapping the first resist film R1 is removed.

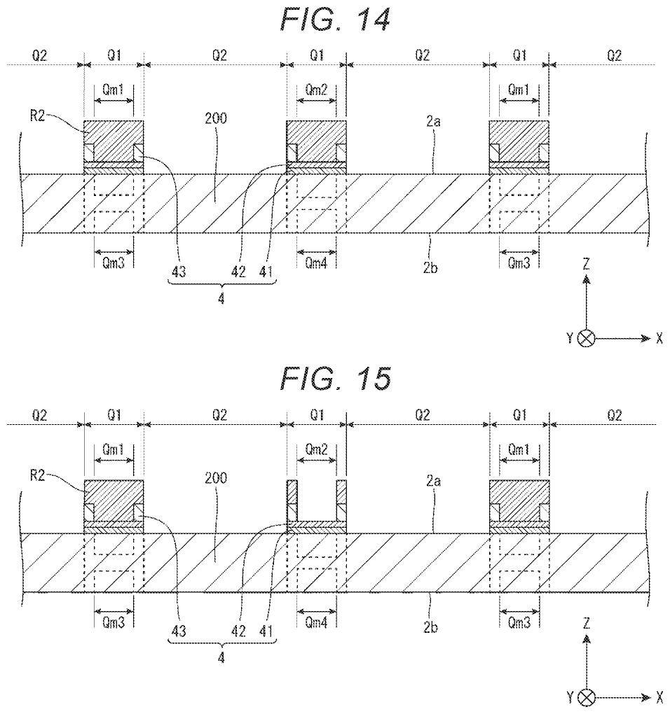

Next, after the first resist film R1 is removed, as shown in FIG. 13, a second resist film R2 is formed on the first stacked body 4, and is patterned using a photolithography technique. The second resist film R2 overlaps the element formation region Q1. Next, as shown in FIG. 14, the first stacked body 4 is etched from the upper surface 2a through the second resist film R2, and a portion not overlapping the second resist film R2 is removed. This step includes etching the second underlying film 42 through the second resist film R2 and etching the first underlying film 41 through the second resist film R2. Accordingly, etching can be performed under conditions suitable for the films 41 and 42.

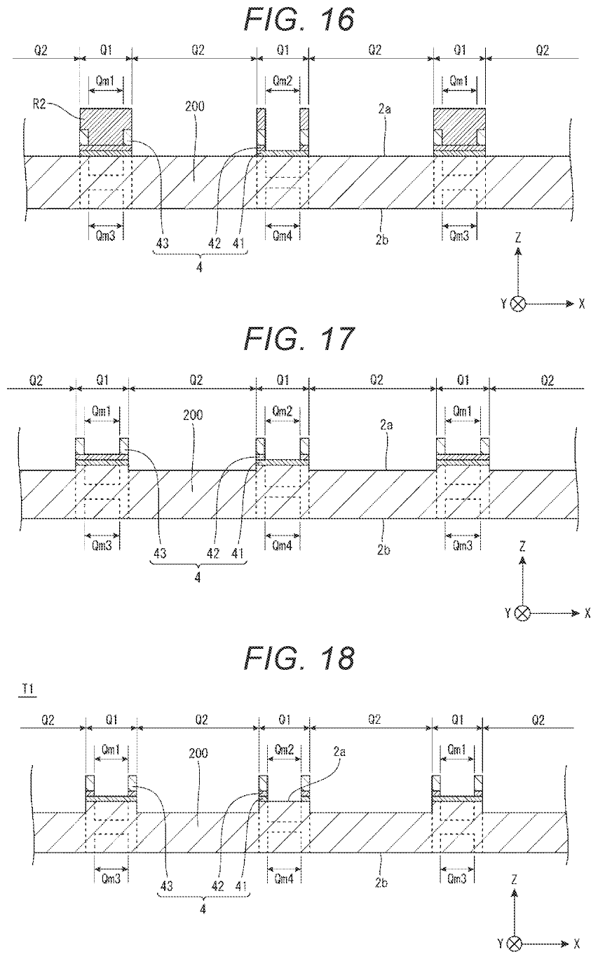

Next, as shown in FIG. 15, a portion of the second resist film R2 overlapping the second groove formation region Qm2 is removed to expose the first stacked body 4 on the second groove formation region Qm2. Next, as shown in FIG. 16, the second underlying film 42 is etched from the upper surface 2a through the second resist film R2, and a portion not overlapping the second resist film R2 is removed. Then, the second resist film R2 is removed.

Through the above steps, the first stacked body 4 is obtained, in which the first underlying film 41, the second underlying film 42, and the first protective film 43 remain in a region of the element formation region Q1 other than the first groove formation region Qm1 and the second groove formation region Qm2, the first underlying film 41 and the second underlying film 42 remain in the first groove formation region Qm1, and the first underlying film 41 remains in the second groove formation region Qm2.

### First Dry Etching Step S4

Next, the quartz crystal substrate 200 is dry-etched from the upper surface 2a through the first stacked body 4. Since the dry etching can be performed without being affected by a crystal plane of quartz crystal, good dimension accuracy can be obtained. Dry etching is reactive ion etching and is performed using a reactive ion etching (RIE) device. A reactive gas introduced into the RIE device is not particularly limited, and for example, SF₆, CF₄, C₂F₄, C₂F₆, C₃F₆, or C₄F₈ can be used.

When this step is started, first, as shown in FIG. 17, etching of the removal region Q2 exposed from the first stacked body 4 is started. Accordingly, first, formation of the outer shape of the vibration substrate 2 is started. Then, when the etching proceeds, as shown in FIG. 18, at a predetermined time T1, the first underlying film 41 in the second groove formation region Qm2 disappears, and etching of the second groove formation region Qm2 is started. Accordingly, the formation of the second groove A21 is started later than the formation of the outer shape of the vibration substrate 2. Further, when the etching proceeds, as shown in FIG. 19, at a predetermined time T2, the first underlying film 41 and the second underlying film 42 in the first groove formation region Qm1 disappear, and etching of the first groove formation region Qm1 is started. Accordingly, the formation of the first groove A11 is started later than the formation of the second groove A21.

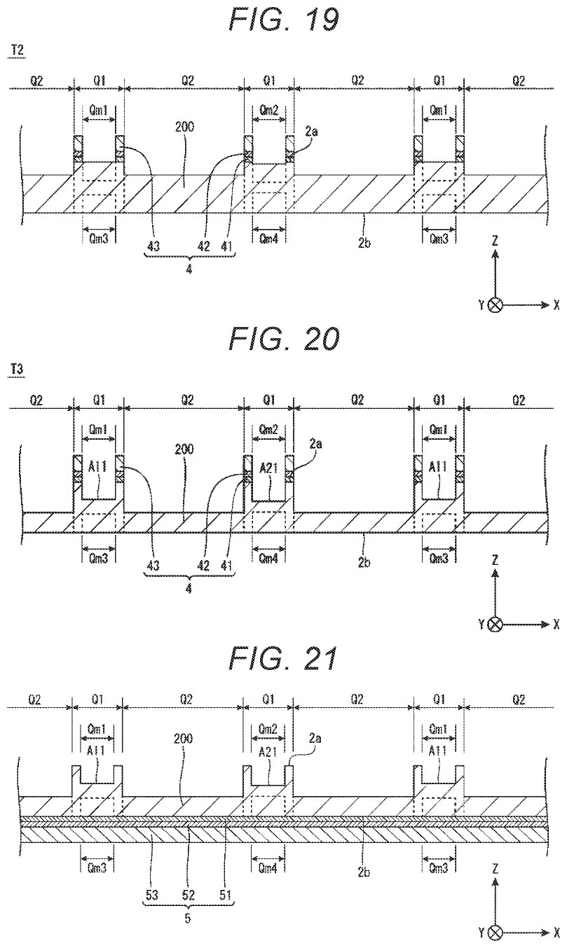

Then, as shown in FIG. 20, the dry etching is ended at a time T3 when both the first groove A11 and the second groove A21 reach a predetermined depth. Accordingly, the first groove A11 and the second groove A21 are collectively formed. At the time T3, an etching depth of the removal region Q2 reaches half or more of a thickness of the quartz crystal substrate 200. That is, in the embodiment, film thicknesses of the first and second underlying films 41 and 42 are designed such that the first groove A11 and the second groove A21 reach a predetermined depth at the same time and an etching depth of the removal region Q2 at that time reaches half or more of a thickness of the quartz crystal substrate 200.

As described above, in this step, the first stacked body 4 in the second groove formation region Qm2 and the first stacked body 4 in the first groove formation region Qm1 are sequentially removed, and the dry etching is started in order of the removal region Q2, the second groove formation region Qm2, and the first groove formation region Qm1. Therefore, an etching depth of the second groove formation region Qm2 is smaller than an etching depth of the removal region Q2, and an etching depth of the first groove formation region Qm1 is smaller than the etching depth of the second groove formation region Qm2. Accordingly, the first groove A11 and the second groove A21 having different depths can be collectively formed in one step, and the first groove A11 and the second groove A21 can be easily formed.

Further, according to such a step, since the predetermined times T1 and T2 can be controlled by the film thicknesses of the first and second underlying films 41 and 42, etching depths of the removal region Q2, the second groove formation region Qm2, and the first groove formation region Qm1 can be independently controlled in an easy and accurate manner. Accordingly, depths of the first groove A11 and the second groove A21 can be freely set.

As described above, the step of etching the quartz crystal substrate 200 from the upper surface is completed. The following steps S5 to S7 are steps of etching the quartz crystal substrate 200 from the lower surface, and are similar to the above-described steps S2 to S4. Therefore, description of contents overlapping the steps S2 to S4 will be omitted.

### Second Film Formation Step S5

Next, as shown in FIG. 21, a third underlying film 51, a fourth underlying film 52, and a second protective film 53 are formed in this order on the lower surface 2b of the quartz crystal substrate 200 to form a second stacked body 5. The second stacked body 5 has the same configuration as the first stacked body 4 described above, and the third underlying film 51 corresponds to the first underlying film 41, the fourth underlying film 52 corresponds to the second underlying film 42, and the second protective film 53 corresponds to the first protective film 43. Therefore, detailed description of the second stacked body 5 is omitted.

### Second Patterning Step S6

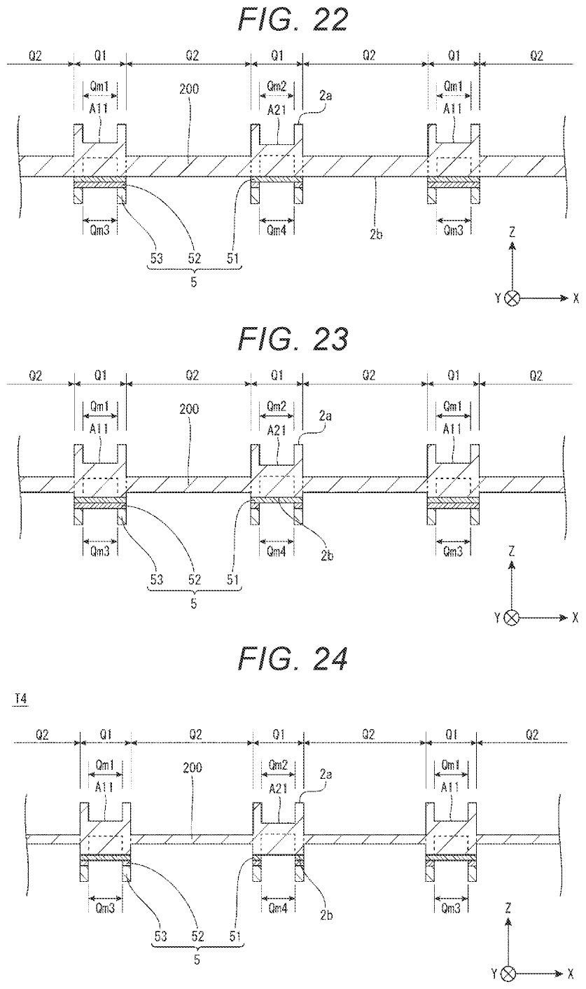

Next, as shown in FIG. 22, the second stacked body 5 is patterned, the third underlying film 51, the fourth underlying film 52, and the second protective film 53 remain in a region of the element formation region Q1 other than the third groove formation region Qm3 and the fourth groove formation region Qm4, the third underlying film 51 and the fourth underlying film 52 remain in the third groove formation region Qm3, and the third underlying film 51 remains in the fourth groove formation region Qm4. The patterning of the second stacked body 5 can be performed by a step similar to the above-described first patterning step S3. Therefore, detailed description of a patterning method of the second stacked body 5 is omitted.

### Second Dry Etching Step S7

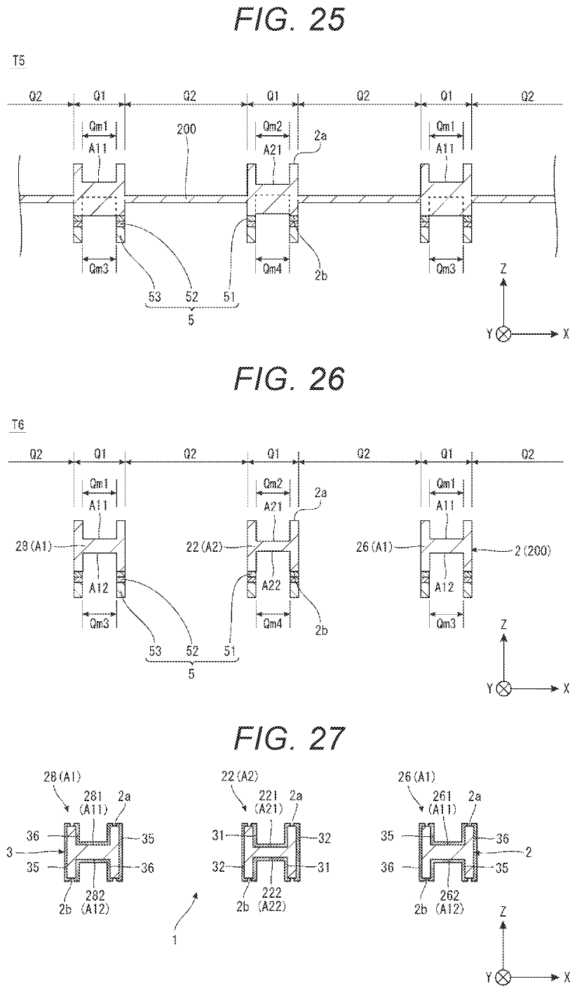

Next, the quartz crystal substrate 200 is dry-etched from the lower surface 2b through the second stacked body 5. When this step is started, first, as shown in FIG. 23, etching of the removal region Q2 exposed from the second stacked body 5 is started. Accordingly, formation of the outer shape of the vibration substrate 2 is started. When the etching proceeds, as shown in FIG. 24, at a predetermined time T4, the third underlying film 51 in the fourth groove formation region Qm4 disappears, and etching of the fourth groove formation region Qm4 is started. Accordingly, the formation of the fourth groove A22 is started later than the formation of the outer shape of the vibration substrate 2. Further, when the etching proceeds, as shown in FIG. 25, at a predetermined time T5, the third underlying film 51 and the fourth underlying film 52 in the third groove formation region Qm3 disappear, and etching of the third groove formation region Qm3 is started. Accordingly, the formation of the third groove A12 is started later than the formation of the fourth groove A22.

Then, as shown in FIG. 26, the dry etching is ended at a time T6 when both the third groove A12 and the fourth groove A22 reach a predetermined depth. Accordingly, the third groove A12 and the fourth groove A22 are collectively formed. At the time T6, the quartz crystal substrate 200 is etched through in the removal region Q2, and the outer shape of the vibration substrate 2 is finished. Accordingly, a further dry etching step for finishing the outer shape of the vibration substrate 2 is not necessary, and thus the number of manufacturing steps of the vibrator 1 can be reduced and the cost of the vibrator 1 can be reduced.

A plurality of vibration substrates 2 are obtained from the quartz crystal substrate 200 by performing the above steps.

### Electrode Formation Step S8

Next, after the first stacked body 4 and the second stacked body 5 are removed from the quartz crystal substrate 200, as shown in FIG. 27, the electrode 3 is formed on a surface of the vibration substrate 2. A method of forming the electrode 3 is not particularly limited, and for example, the electrode 3 can be obtained by forming a metal film on the surface of the vibration substrate 2 and patterning the metal film using a photolithography technique and an etching technique.

The vibrator 1 is obtained by performing the above steps. According to such a manufacturing method, the first groove A11 and the second groove A21 having different depths can be collectively formed in an easy manner. Similarly, the third groove A12 and the fourth groove A22 having different depths can be collectively formed in an easy manner. A positional deviation of the grooves A11, A21, A12, and A22 relative to the outer shape of the vibration substrate 2 is prevented, and formation accuracy of the vibration substrate 2 is improved. Further, since the micro loading effect is not used, a restriction on a shape and a dimension of the vibration substrate 2 and a restriction on dry etching conditions such as selection of a reaction gas used for dry etching are reduced. Accordingly, the vibrator 1 having a high degree of freedom in design can be easily manufactured with high accuracy.

In the embodiment, the removal region Q2 of the quartz crystal substrate 200 is not etched through until the second dry etching step S7, and a mechanical strength of the quartz crystal substrate 200 can be maintained sufficiently high. That is, steps up to the second dry etching step S7 that is a final stage can be performed in a state in which the mechanical strength of the quartz crystal substrate 200 remains high. Therefore, handleability is improved, and the vibrator 1 is easily manufactured.

The present disclosure is not limited thereto, and for example, the removal region Q2 of the quartz crystal substrate 200 may be etched through in the first dry etching step S4. That is, in the first dry etching step S4, the outer shape of the vibration substrate 2 may be finished. Since the outer shape of the vibration substrate 2 is formed by dry etching from the upper surface 2a, the outer shape can be finished using only the first stacked body 4. Therefore, the outer shape can be formed with high accuracy. Accordingly, unnecessary vibrations of the first and second vibration arms A1 and A2 and a decrease in vibration balance are prevented, and the vibrator 1 having excellent angular velocity detection characteristics can be manufactured.

The method for manufacturing the vibrator 1 is described above. As described above, such a manufacturing method is a method for manufacturing the vibrator 1 including the first vibration arm A1 that has the upper surface 2a serving as the first surface and the lower surface 2b serving as the second surface which are in a front and back relationship and that has the bottomed first groove A11 opened in the upper surface 2a, and the second vibration arm A2 that has the bottomed second groove A21 opened in the upper surface 2a. The method includes: the preparation step S1 of preparing the quartz crystal substrate 200 having the upper surface 2a and the lower surface 2b; the first film formation step S2 of forming the first stacked body 4 by sequentially stacking the first underlying film 41, the second underlying film 42, and the first protective film 43 at the upper surface 2a, the first patterning step S3 of patterning the first stacked body 4 in a manner in which the first underlying film 41, the second underlying film 42, and the first protective film 43 remain in a region of the element formation region Q1 other than the first groove formation region Qm1 and the second groove formation region Qm2, the first underlying film 41 and the second underlying film 42 remain in the first groove formation region Qm1, and the first underlying film 41 remains in the second groove formation region Qm2, when a region of the quartz crystal substrate 200 where the vibrator 1 is formed is referred to as the element formation region Q1, a region where the first groove A11 is formed is referred to as the first groove formation region Qm1, and a region where the second groove A21 is formed is referred to as the second groove formation region Qm2; and a first dry etching step S4 of dry etching the quartz crystal substrate 200 from the upper surface 2a through the first stacked body 4.

According to such a manufacturing method, etching start times of the first groove formation region Qm1 and the second groove formation region Qm2 can be made different. Accordingly, the first groove A11 and the second groove A21 having different depths can be collectively formed in an easy manner. Therefore, the number of manufacturing steps of the vibrator 1 can be reduced, and the cost of the vibrator 1 can be reduced. A positional deviation of the first and second grooves A11 and A21 relative to the outer shape of the vibration substrate 2 is prevented, and formation accuracy of the vibration substrate 2 is improved. Further, since the micro loading effect is not used, a restriction on a shape and a dimension of the vibration substrate 2 and a restriction on dry etching conditions such as selection of a reaction gas used for dry etching are reduced. Accordingly, the vibrator 1 having a high degree of freedom in design can be easily manufactured with high accuracy.

Further, as described above, the first stacked body 4 in the second groove formation region Qm2 and the first stacked body 4 in the first groove formation region Qm1 are sequentially removed in the first dry etching step S4, and the dry etching is started in order of the removal region Q2 other than the element formation region Q1, the second groove formation region Qm2, and the first groove formation region Qm1. Therefore, an etching depth of the second groove formation region Qm2 is smaller than an etching depth of the removal region Q2, and an etching depth of the first groove formation region Qm1 is smaller than the etching depth of the second groove formation region Qm2. According to such a step, since film thicknesses of the first and second underlying films 41 and 42 can be controlled, etching depths of the removal region Q2, the second groove formation region Qm2, and the first groove formation region Qm1 can be independently controlled in a more easy and accurate manner, and the first and second grooves A11 and A21 having different depths can be collectively formed in one step.

As described above, the vibrator 1 includes the bottomed third groove A12 opened in the lower surface 2b of the first vibration arm A1 and the bottomed fourth groove A22 opened in the lower surface 2b of the second vibration arm A2, and the method for manufacturing the vibrator 1 further includes the second film formation step S5 of forming the second stacked body 5 by forming the third underlying film 51, the fourth underlying film 52, and the second protective film 53 at the lower surface 2b; the second patterning step S6 of patterning the second stacked body 5 in a manner in which the third underlying film 51, the fourth underlying film 52, and the second protective film 53 remain in a region of the element formation region Q1 other than the third groove formation region Qm3 and the fourth groove formation region Qm4, the third underlying film 51 and the fourth underlying film 52 remain in the third groove formation region Qm3, and the third underlying film 51 remains in the fourth groove formation region Qm4, when a region of the quartz crystal substrate 200 where the third groove A12 is formed is referred to as the third groove formation region Qm3 and a region where the fourth groove A22 is formed is referred to as the fourth groove formation region Qm4; and the second dry etching step S7 of dry etching the quartz crystal substrate 200 from the lower surface 2b through the second stacked body 5.

According to such a manufacturing method, the third groove A12 and the fourth groove A22 having different depths can be collectively formed in an easy manner. Therefore, the number of manufacturing steps of the vibrator 1 can be reduced, and the cost of the vibrator 1 can be reduced. A positional deviation of the third and fourth grooves A12 and A22 relative to the outer shape of the vibration substrate 2 is prevented, and formation accuracy of the vibration substrate 2 is improved.

As described above, the vibrator 1 is an angular velocity detection element configured to detect an angular velocity, the first vibration arm A1 performs a flexural vibration in response to an applied drive signal, and the second vibration arm A2 performs a flexural vibration in response to an applied angular velocity ωz. That is, the first vibration arm A1 is the drive vibration arms 26, 27, 28, and 29, and the second vibration arm A2 is the detection vibration arms 22 and 23. Accordingly, since the first grooves A11 formed in the drive vibration arms 26, 27, 28, and 29 are shallower than the second grooves A21 formed in the detection vibration arms 22 and 23, detection sensitivity of the angular velocity detection element can be improved.

As described above, the vibrator 1 includes the base portion 21, the pair of detection vibration arms 22 and 23 serving as the second vibration arm A2 extending from the base portion 21 to both sides in the Y-axis direction which is a first direction, the pair of support arms 24 and 25 extending from the base portion 21 to both sides in the X-axis direction which is a second direction intersecting the Y-axis direction, the pair of drive vibration arms 26 and 27 serving as the first vibration arm A1 extending from the support arm 24 to both sides in the Y-axis direction, and the pair of drive vibration arms 28 and 29 serving as the first vibration arm A1 extending from the support arm 25 to both sides in the Y-axis direction. According to such a configuration, since the drive vibration arms 26, 27, 28, and 29 perform flexural vibrations in a balanced manner in a drive vibration mode, an unnecessary vibration is less likely to occur in the detection vibration arms 22 and 23, and the angular velocity ωz can be accurately detected.

As described above, at least one of the first underlying film 41 and the second underlying film 42 is a metal film. In particular, the first underlying film 41 and the second underlying film 42 are both metal films in the embodiment. Accordingly, excellent etching resistance (high etching rate ratio) can be exhibited, and the films 41 and 42 can be thinned. Therefore, time required for forming the first stacked body 4 can be shortened, and a manufacturing time of the vibrator 1 can be shortened. The film thicknesses of the first underlying film 41 and the second underlying film 42 can be controlled with high accuracy. Therefore, a timing at which the first underlying film 41 and the second underlying film 42 are removed in the first dry etching step S4, that is, the predetermined times T1 and T2 can be controlled with high accuracy. Therefore, the first groove A11 and the second groove A21 can be formed with high accuracy.

### Second Embodiment

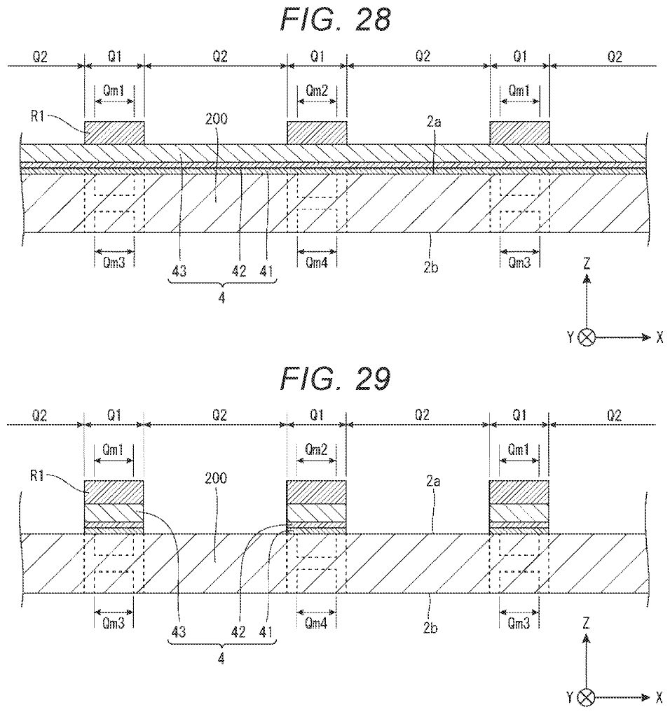

FIGS. 28 to 33 are cross-sectional views showing a method for manufacturing a vibrator according to a second embodiment.

The method for manufacturing the vibrator according to the embodiment is similar to the method for manufacturing the vibrator according to the first embodiment except that the first patterning step S3 and the second patterning step S6 are different. Therefore, in the following description, the method for manufacturing the vibrator according to the embodiment will be described with a focus on differences from the first embodiment described above, and description of similar matters will be omitted. In the drawings of the embodiment, configurations the same as those of the above embodiments will be denoted by the same reference numerals. Since the second patterning step S6 is similar to the first patterning step S3, the first patterning step S3 will be described below as a representative, and description of the second patterning step S6 will be omitted.

### First Patterning Step S3

First, as shown in FIG. 28, the first resist film R1 is formed on the first stacked body 4 and is patterned using a photolithography technique. The first resist film R1 overlaps the element formation region Q1. Next, as shown in FIG. 29, the first stacked body 4 is etched from the upper surface 2a through the first resist film R1, and a portion not overlapping the first resist film R1 is removed.

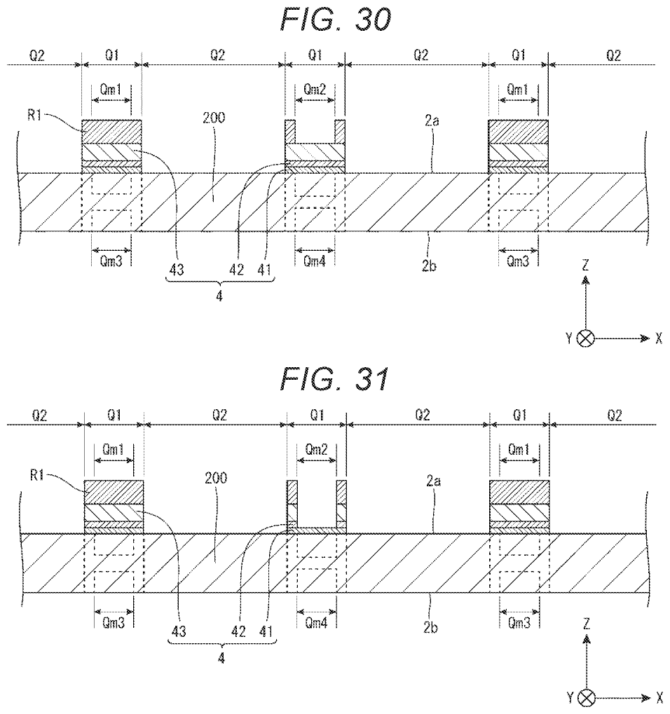

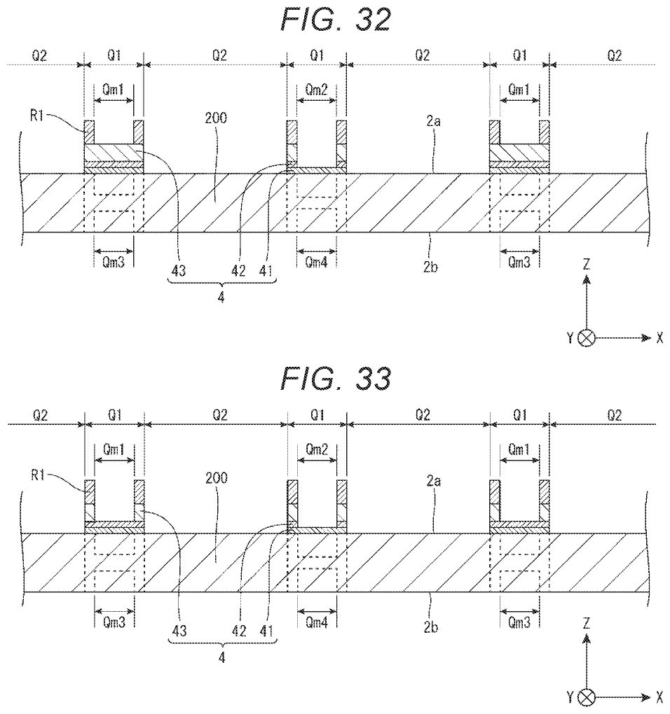

Next, as shown in FIG. 30, the first resist film R1 in the second groove formation region Qm2 is removed. Next, as shown in FIG. 31, the first stacked body 4 is etched through the first resist film R1, and the first protective film 43 and the second underlying film 42 in the second groove formation region Qm2 are removed. Next, as shown in FIG. 32, the first resist film R1 in the first groove formation region Qm1 is removed. Next, as shown in FIG. 33, the first stacked body 4 is etched through the first resist film R1, and the first protective film 43 in the first groove formation region Qm1 is removed. Through the above steps, the first stacked body 4 is obtained, in which the first underlying film 41, the second underlying film 42, and the first protective film 43 remain in a region of the element formation region Q1 other than the first groove formation region Qm1 and the second groove formation region Qm2, the first underlying film 41 and the second underlying film 42 remain in the first groove formation region Qm1, and the first underlying film 41 remains in the second groove formation region Qm2. According to such a method, the first stacked body 4 can also be easily patterned.

The second embodiment as described above can also exhibit the same effect as the first embodiment described above.

### Third Embodiment

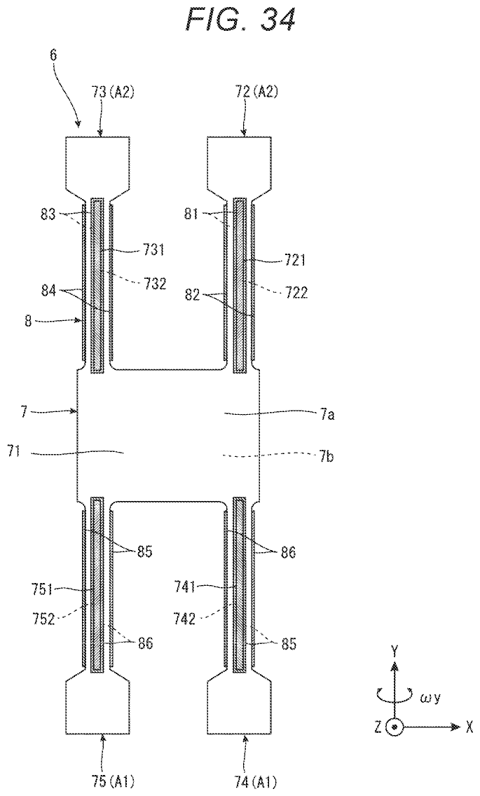

FIG. 34 is a plan view showing a vibrator according to a third embodiment.

The method for manufacturing the vibrator according to the embodiment is similar to the method for manufacturing the vibrator according to the first embodiment described above except that a configuration of the vibrator to be manufactured is different. In the following description, the method for manufacturing the vibrator according to the embodiment will be described with a focus on differences from the first embodiment described above, and description of similar matters will be omitted. In the drawings of the embodiment, configurations the same as those of the above embodiments will be denoted by the same reference numerals.

In the method for manufacturing the vibrator according to the embodiment, a vibrator 6 shown in FIG. 34 is manufactured. The vibrator 6 is an angular velocity detection element capable of detecting an angular velocity ωy around the Y axis. The vibrator 6 includes a vibration substrate 7 formed by patterning a Z-cut quartz crystal substrate, and an electrode 8 formed on a surface of the vibration substrate 7.

The vibration substrate 7 has a plate shape and has an upper surface 7a serving as a first surface and a lower surface 7b serving as a second surface which are in a front and back relationship. The vibration substrate 7 includes a base portion 71 located in a center portion of the vibration substrate 7, a pair of detection vibration arms 72 and 73 serving as the second vibration arm A2 extending from the base portion 71 to a positive side of the Y-axis direction, and a pair of drive vibration arms 74 and 75 serving as the first vibration arm A1 extending from the base portion 71 to a negative side of the Y-axis direction. The pair of detection vibration arms 72 and 73 are arranged side by side in the X-axis direction, and the pair of drive vibration arms 74 and 75 are arranged side by side in the X-axis direction.

The detection vibration arm 72 has a bottomed groove 721 serving as a second groove formed in the upper surface 7a and a bottomed groove 722 serving as a fourth groove formed in the lower surface 7b. Similarly, the detection vibration arm 73 has a bottomed groove 731 serving as the second groove formed in the upper surface 7a and a bottomed groove 732 serving as the fourth groove formed in the lower surface 7b.

The drive vibration arm 74 has a bottomed groove 741 serving as a first groove formed in the upper surface 7a and a bottomed groove 742 serving as a third groove formed in the lower surface 7b. Similarly, the drive vibration arm 75 has a bottomed groove 751 serving as the first groove formed in the upper surface 7a and a bottomed groove 752 serving as the third groove formed in the lower surface 7b.

The electrode 8 includes a first detection signal electrode 81, a first detection ground electrode 82, a second detection signal electrode 83, a second detection ground electrode 84, a drive signal electrode 85, and a drive ground electrode 86.

Among the electrodes, the first detection signal electrode 81 is disposed on the upper surface 7a and the lower surface 7b of the detection vibration arm 72, and the first detection ground electrode 82 is disposed on both side surfaces of the detection vibration arm 72. The second detection signal electrode 83 is disposed on the upper surface 7a and the lower surface 7b of the detection vibration arm 73, and the second detection ground electrode 84 is disposed on both side surfaces of the detection vibration arm 73. The drive signal electrode 85 is disposed on the upper surface 7a and the lower surface 7b of the drive vibration arm 74 and on both side surfaces of the drive vibration arm 75, and the drive ground electrode 86 is disposed on both side surfaces of the drive vibration arm 74 and on the upper surface 7a and the lower surface 7b of the drive vibration arm 75.

The third embodiment can also exhibit the same effect as the first embodiment described above.

Although the method for manufacturing the vibrator element according to the present disclosure has been described above based on the illustrated embodiments, the present disclosure is not limited thereto. A configuration of each part can be replaced with any configuration having the same function. Any other components may be added to the present disclosure. The vibrator is not limited to the vibrators 1 and 6 described above, and may be, for example, a tuning fork type vibrator or a double-tuning fork type vibrator. The vibrator is not limited to an angular velocity detection element.

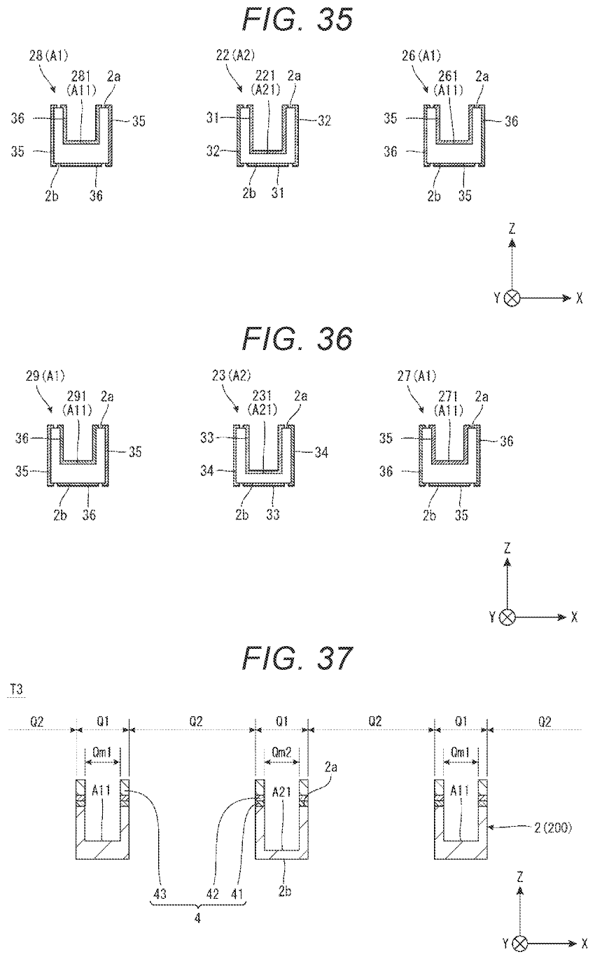

In the vibrator 1, for example, the third and fourth grooves A12 and A22 may be omitted as shown in FIGS. 35 and 36. In this case, the method for manufacturing the vibrator 1 includes the preparation step S1, the first film formation step S2, the first patterning step S3, the first dry etching step S4, and the electrode formation step S8. As shown in FIG. 37, in the first dry etching step S4, at the time T3 when the first and second grooves A11 and A21 reach a predetermined depth, the film thicknesses of the first and second underlying films 41 and 42 may be controlled such that the removal region Q2 is already etched through. Accordingly, the outer shape of the vibration substrate 2 and the first and second grooves A11 and A21 can be collectively formed.

What is claimed is:

1. A method for manufacturing a vibrator, the vibrator including a first vibration arm that has a first surface and a second surface which are in a front and back relationship and that has a bottomed first groove opened in the first surface, and a second vibration arm that has a bottomed second groove opened in the first surface, the method comprising:
a preparation step of preparing a quartz crystal substrate having the first surface and the second surface;
a first film formation step of forming a first stacked body by sequentially stacking a first underlying film, a second underlying film, and a first protective film at the first surface;
a first patterning step of patterning the first stacked body in a manner in which the first underlying film, the second underlying film, and the first protective film remain in a region of an element formation region other than a first groove formation region and a second groove formation region, the first underlying film and the second underlying film remain in the first groove formation region, and the first underlying film remains in the second groove formation region, when a region of the quartz crystal substrate where the vibrator is formed is referred to as the element formation region, a region where the first groove is formed is referred to as the first groove formation region, and a region where the second groove is formed is referred to as the second groove formation region; and
a first dry etching step of dry etching the quartz crystal substrate from the first surface through the first stacked body.

2. The method for manufacturing the vibrator according to claim 1, wherein
the first stacked body in the second groove formation region and the first stacked body in the first groove formation region sequentially disappear in the first dry etching step, and the dry etching is started in order of a removal region other than the element formation region, the second groove formation region, and the first groove formation region.

3. The method for manufacturing the vibrator according to claim 1, wherein
at least one of the first underlying film and the second underlying film is a metal film.

4. The method for manufacturing the vibrator according to claim 1, wherein
the vibrator has a bottomed third groove opened in the second surface of the first vibration arm and a bottomed fourth groove opened in the second surface of the second vibration arm, and
the method comprises:
a second film formation step of forming a second stacked body by sequentially stacking a third underlying film, a fourth underlying film, and a second protective film at the second surface;
a second patterning step of patterning the second stacked body in a manner in which the third underlying film, the fourth underlying film, and the second protective film remain in a region of the element formation region other than a third groove formation region and a fourth groove formation region, the third underlying film and the fourth underlying film remain in the third groove formation region, and the third underlying film remains in the fourth groove formation region, when a region of the quartz crystal substrate where the third groove is formed is referred to as the third groove formation region and a region where the fourth groove is formed is referred to as the fourth groove formation region; and
a second dry etching step of dry etching the quartz crystal substrate from the second surface through the second stacked body.

5. The method for manufacturing the vibrator according to claim 1, wherein
the vibrator is an angular velocity detection element configured to detect an angular velocity,
the first vibration arm performs a flexural vibration in response to an applied drive signal, and
the second vibration arm performs a flexural vibration in response to an applied angular velocity.

6. The method for manufacturing the vibrator according to claim 5, wherein
the vibrator includes a base portion, a pair of the second vibration arms extending from the base portion to both sides in a first direction, a pair of support arms extending from the base portion to both sides in a second direction intersecting the first direction, a pair of the first vibration arms extending from one of the support arms to both sides in the first direction, and a pair of the first vibration arms extending from the other one of the support arms to both sides in the first direction.
